(19) United States
(12) Patent Application Publication
(10) Pub. No.: US 2024/0128725 A1
(43) Pub. Date: Apr. 18, 2024

(54) SURFACE-EMITTING LASER ARRAY, LIGHT SOURCE MODULE, AND DISTANCE-MEASURING APPARATUS

(71) Applicants: Kazuma IZUMIYA, Miyagi (JP); Naoto JIKUTANI, Miyagi (JP); Kazuhiro HARASAKA, Miyagi (JP)

(72) Inventors: Kazuma IZUMIYA, Miyagi (JP); Naoto JIKUTANI, Miyagi (JP); Kazuhiro HARASAKA, Miyagi (JP)

(21) Appl. No.: 18/277,387

(22) PCT Filed: Feb. 8, 2022
(86) PCT No.: PCT/IB2022/051096

§ 371 Date: Aug. 16, 2023

(30) Foreign Application Priority Data
Mar. 12, 2021 (JP) 2021-040536

(51) Int. Cl. H01S 5/42; G01S 7/481; G01S 17/08; H01S 5/0233; H01S 5/0237; H01S 5/042; H01S 5/183; H01S 5/40

(52) U.S. Cl. CPC H01S 5/426; G01S 7/4817; G01S 17/08; H01S 5/0233; H01S 5/0237; H01S 5/04257; H01S 5/18305; H01S 5/4018

(57) ABSTRACT

A surface-emitting laser array includes a substrate and a sub-arrays disposed on the substrate, the sub-arrays including a surface-emitting laser devices electrically connected to each other in parallel to emit light through the substrate, each of the surface-emitting laser devices having a light-emitting point and including a first semi-conducting layer of first conductivity. The laser array further includes a second semi-conducting layer of second conductivity, and a resonator disposed between the first semi-conducting layer and the second semi-conducting layer. The sub-arrays adjacent to each other include an electrode to electrically connect the first semi-conducting layer in the surface-emitting laser devices included in one of the sub-arrays and the second semi-conducting layer.

### TECHNICAL FIELD

Embodiments of the present disclosure relate to a surface-emitting laser array, a light source module, and a distance-measuring apparatus.

### BACKGROUND ART

Currently, range finders such as light detection and ranging (LiDAR) devices that adopt time of flight (TOF) methodologies become rapidly widespread. As a key device of such range finders, a vertical-cavity surface-emitting laser (VCSEL) array meets expectations. As the VCSEL array enables building a two-dimensional array, the design and installation of light sources are easy, and changes in temperature due to changes in wavelengths are small.

In the related art, for the purposes of reducing the driving current of a VCSEL array, a configuration in which the surface-emitting laser devices are electrically connected in series is proposed.

### CITATION LIST

### Patent Literature

[PTL 1]
Japanese Unexamined Patent Application Publication No. 2020-123710

[PTL2]
US Patent Application Publication No. 2019/0036308

[PTL 3]
Japanese Unexamined Patent Application Publication No. 20215-510279

### SUMMARY OF INVENTION

### Technical Problem

There is room for improvement in miniaturization of conventional VCSEL arrays.

### Solution to Problem

A surface-emitting laser array according to an embodiment of the present disclosure includes a substrate, a plurality of sub-arrays disposed on the substrate, the plurality of sub-arrays including a plurality of surface-emitting laser devices electrically connected to each other in parallel to emit light through the substrate, each of the plurality of surface-emitting laser devices having a light-emitting point and including a first semi-conducting layer of first conductivity, a second semi-conducting layer of second conductivity, and a resonator disposed between the first semi-conducting layer and the second semi-conducting layer. The plurality of sub-arrays that are adjacent to each other include an electrode configured to electrically connect the first semi-conducting layer in the plurality of surface-emitting laser devices included in one of the plurality of sub-arrays and the second semi-conducting layer in the plurality of surface-emitting laser devices included in another one of the plurality of sub-arrays, and the plurality of sub-arrays are electrically connected in series.

### Advantageous Effects of Invention

With the technologies according to the embodiments of the present disclosure, miniaturization can be achieved.

### BRIEF DESCRIPTION OF DRAWINGS

The accompanying drawings are intended to depict example embodiments of the present invention and should not be interpreted to limit the scope thereof. The accompanying drawings are not to be considered as drawn to scale unless explicitly noted. Also, identical or similar reference numerals designate identical or similar components throughout the several views.

FIG. 1 is a cross-sectional view of a VCSEL array according to a first embodiment of the present disclosure.

FIG. 2 is a diagram illustrating an equivalent circuit of a VCSEL array according to the first embodiment of the present disclosure.

FIG. 3 is a plan view of a VCSEL array according to the first embodiment of the present disclosure.

FIG. 4 is a first cross-sectional view of a light source module provided with a VCSEL array, according to the first embodiment of the present disclosure.

FIG. 5 is a second cross-sectional view of a light source module provided with a VCSEL array, according to the first embodiment of the present disclosure.

FIG. 6 is a plan view of a VCSEL array according to a modification the first embodiment of the present disclosure.

FIG. 7 is a cross-sectional view of a VCSEL array according to a second embodiment of the present disclosure.

FIG. 8 is a diagram illustrating an equivalent circuit of a VCSEL array according to the second embodiment of the present disclosure.

FIG. 9 is a cross-sectional view of a light source module provided with a VCSEL array, according to the second embodiment of the present disclosure.

FIG. 10 is a cross-sectional view of a VCSEL array 300 according to a third embodiment of the present disclosure.

FIG. 11 is a first cross-sectional view of a method of manufacturing a VCSEL array 300 according to the third embodiment of the present disclosure.

FIG. 12 is a second cross-sectional view of a method of manufacturing a VCSEL array 300 according to the third embodiment of the present disclosure.

FIG. 13 is a third cross-sectional view of a method of manufacturing a VCSEL array 300 according to the third embodiment of the present disclosure.

FIG. 14 is a fourth cross-sectional view of a method of manufacturing a VCSEL array 300 according to the third embodiment of the present disclosure.

FIG. 15 is a fifth cross-sectional view of a method of manufacturing a VCSEL array 300 according to the third embodiment of the present disclosure.

FIG. 16 is a sixth cross-sectional view of a method of manufacturing a VCSEL array 300 according to the third embodiment of the present disclosure.

FIG. 17 is a seventh cross-sectional view of a method of manufacturing a VCSEL array 300 according to the third embodiment of the present disclosure.

FIG. 18 is an eighth cross-sectional view of a method of manufacturing a VCSEL array 300 according to the third embodiment of the present disclosure.

FIG. 19 is a first plan view of a method of manufacturing a VCSEL array 300 according to the third embodiment of the present disclosure.

FIG. 20 is a second plan view of a method of manufacturing a VCSEL array 300 according to the third embodiment of the present disclosure.

FIG. 21 is a cross-sectional view of a VCSEL array according to a fourth embodiment of the present disclosure.

FIG. 22 is a diagram illustrating an equivalent circuit of a VCSEL array according to the fourth embodiment of the present disclosure.

FIG. 23 is a cross-sectional view of a light source module provided with a VCSEL array, according to the fourth embodiment of the present disclosure.

FIG. 24 is a diagram illustrating a configuration of a distance-measuring apparatus according to a fifth embodiment of the present disclosure.

### DESCRIPTION OF EMBODIMENTS

Embodiments of the present disclosure are described below in detail with reference to the accompanying drawings. In the description and the drawings of the embodiments of the present disclosure, like reference signs may be given to like elements with substantially the same functional configuration. Accordingly, overlapping descriptions are omitted where appropriate.

### First Embodiment

Firstly, a first embodiment of the present disclosure is described below. The first embodiment of the present disclosure relates to a vertical-cavity surface-emitting laser (VCSEL) array.

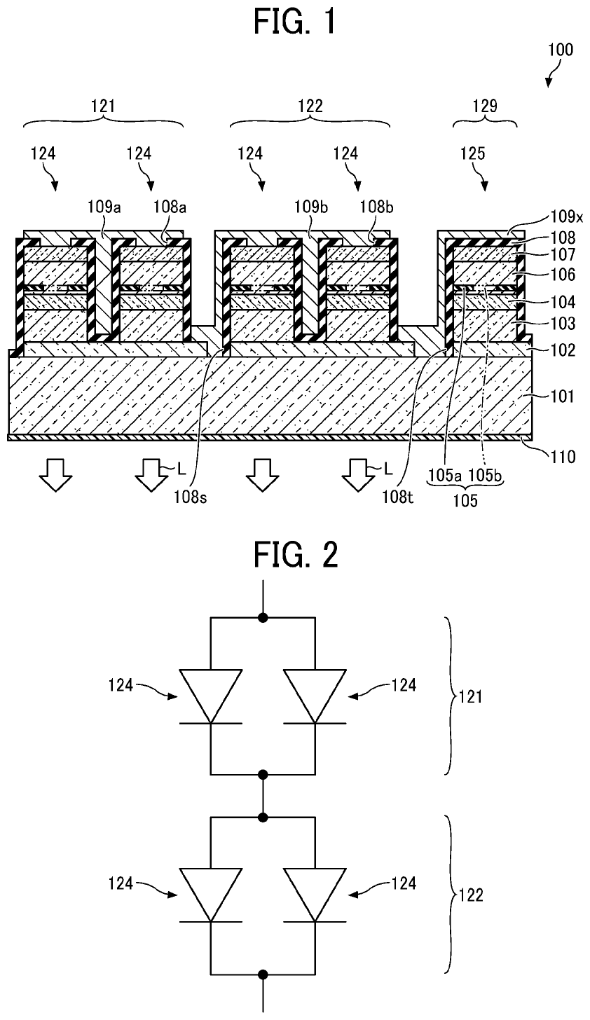

FIG. 1 is a cross-sectional view of a VCSEL array according to the first embodiment of the present disclosure.

FIG. 2 is a diagram illustrating an equivalent circuit of a VCSEL array according to the first embodiment of the present disclosure.

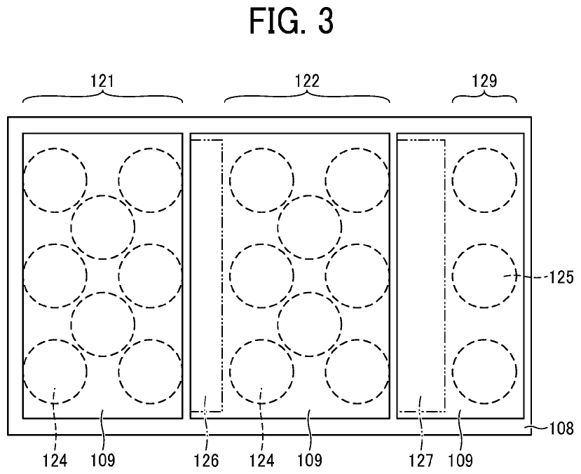

FIG. 3 is a plan view of a VCSEL array according to the first embodiment of the present disclosure.

As illustrated in FIG. 1, the VCSEL array 100 according to the first embodiment includes a substrate 101, a first sub-array 121 and a second sub-array 122 on the substrate 101, and a cathode pad portion 129. As illustrated in FIG. 2, the first sub-array 121 and the second sub-array 122 are coupled to each other in series. Each one of the first sub-array 121 and the second sub-array 122 includes two VCSEL devices 124 that emit light L through the substrate 101. In the first sub-array 121, the two VCSEL devices 124 are electrically connected to each other in parallel. Similarly, in the second sub-array 122, the two VCSEL devices 124 are electrically coupled to each other in parallel. The cathode pad portion 129 according to the present embodiment includes a quasi-VCSEL device 125. As illustrated in FIG. 1 and FIG. 3, the second sub-array 122 is placed between the first sub-array 121 and the cathode pad portion 129. The substrate 101 is, for example, a non-doped semi-insulating GaAs substrate.

Each one of the VCSEL devices 124 includes a first contact layer 102 of first conductivity, a first multilayer reflector 103 of first conductivity, a resonator 104, a second multilayer reflector 106 having second conductivity, and a second contact layer 107 having second conductivity.

The first contact layer 102 overlies the substrate 101. The first contact layer 102 is, for example, a highly doped GaAs layer. Two VCSEL devices 124 included in the first sub-array 121 share one first contact layer 102, and two VCSEL devices 124 included in the second sub-array 122 share one first contact layer 102. The first contact layer 102 according to the present embodiment serves as a first semiconducting layer.

The first multilayer reflector 103 overlies the first contact layer 102. The first multilayer reflector 103 alternately includes two types of layers having different refractive indexes. For example, one of such a pair of layers is a high refractive index layer of Al_{0.2}Ga_{0.8}As, and the other layer of such a pair of layers is a low refractive index layer of Al_{0.9}Ga_{0.1}As. The first multilayer reflector 103 includes a gradient-composition layer in which the composition continuously changes between the high refractive index layer and the low refractive index layer, and the optical thickness of each layer up to the center of the gradient-composition layer is λ/4 where λ denotes the oscillation wavelength of the laser.

The resonator 104 overlies the first multilayer reflector 103. The resonator 104 includes a lower spacer layer, an active layer over the lower spacer layer, and an upper spacer layer over the active layer.

λ denotes optical length of the resonator 104. For example, the oscillation wave length λ is 940 nm.

The second multilayer reflector 106 overlies the resonator 104. The second multilayer reflector 106 alternately includes two types of layers having different refractive indices. For example, one of such a pair of layers is a high refractive index layer of Al_{0.2}Ga_{0.8}As, and the other layer of such a pair of layers is a low refractive index layer of Al_{0.9}Ga_{0.1}As. The second multilayer reflector 106 includes a gradient-composition layer in which the composition continuously changes between the high refractive index layer and the low refractive index layer, and the optical thickness of each layer up to the center of the gradient-composition layer is λ/4 where λ denotes the oscillation wavelength of the laser. The number of pairs of high refractive index layers and low refractive index layers in the second multilayer reflector 106 is larger than the number of pairs of high refractive index layers and low refractive index layers in the first multilayer reflector 103. Due to such a configuration, the VCSEL device 124 can emit light L through the substrate 101.

The second multilayer reflector 106 includes a selective oxidized layer 105. The selective oxidized layer 105 includes an oxidized area 105a and a non-oxidized area 105b. The Al composition of the selective oxidized layer 105 is higher than that of the surrounding layers, and for example, the selective oxidized layer 105 is an AlAs layer.

The second contact layer 107 overlies the second multilayer reflector 106. The second contact layer 107 is, for example, a highly doped GaAs layer. The second contact layer 107 according to the present embodiment serves as a second semiconducting layer.

The quasi-VCSEL device 125 has a multilayered structure equivalent to that of the VCSEL devices 124.

The VCSEL array 100 includes an insulating layer 108 that covers the VCSEL devices 124 and the quasi-VCSEL device 125. The insulating layer 108 is, for example, a SiN layer or a SiO₂ layer. The insulating layer 108 has an opening 108a that exposes the second contact layers 107 of the two VCSEL devices 124 included in the first sub-array 121 and an opening 108b that exposes the second contact layers 107 of the two VCSEL devices 124 included in the second sub-array 122. The insulating layer 108 does not have an opening that exposes the second contact layer 107 of the quasi-VCSEL device 125. The insulating layer 108 has an opening 108s exposing the first contact layer 102 included in the first sub-array 121 and an opening 108t exposing the first contact layer 102 included in the second sub-array 122.

The VCSEL array 100 includes an electrode 109a, an electrode 109b, and an electrode 109x that are disposed on the insulating layer 108. The electrode 109a contacts the second contact layers 107 of the two VCSEL devices 124 included in the first sub-array 121 through the opening 108a. The electrode 109b contacts the second contact layers 107 of the two VCSEL devices 124 included in the second sub-array 122 through the opening 108b. The electrode 109b also contacts the first contact layer 102 included in the first sub-array 121 in the contact region 126 (see FIG. 3). The electrode 109x is disposed on the insulating layer 108 in the cathode pad portion 129, but does not contact the second contact layer 107 of the quasi-VCSEL device 125. The electrode 109x contacts the first contact layer 102 included in the second sub-array 122 in the contact region 127 (see FIG. 3). The contact region 126 corresponds to the opening 108s, and the contact region 127 corresponds to the opening 108t. Each of the electrodes 109a, 109b, and 109x is, for example, a stacked body including a Ti film, a Pt film on the Ti film, and an Au-film on the Pt film. A base layer for ohmic connection with the first contact layer 102 and a base layer for ohmic connection with the second contact layer 107 may be different from each other.

The VCSEL array 100 has an antireflection film 110 on the rear side of the substrate 101 from which light is not emitted. The optical thickness of the antireflection film 110 is indicated by λ/4.

In the VCSEL array 100 according to the first embodiment, the first contact layer 102 of the first sub-array 121 and the second contact layer 107 of the second sub-array 122 are not electrically connected to each other through the substrate 101. An electrode 109b electrically connects the first contact layer 102 in the first sub-array 121 and the second contact layer 107 in the second sub-array 122. Due to such a configuration, the first sub-array 121 and the second sub-array 122 are connected in series. Accordingly, according to the first embodiment, the drive current can be reduced to approximately half as compared with the case where all the VCSEL devices 124 are connected in parallel.

When a potential difference is applied between the electrode 109a and the electrode 109x, the VCSEL array 100 can be driven. Accordingly, it is not always necessary to implement an anode pad and a cathode pad in each of the first sub-array 121 and the second sub-array 122. Such a configuration allows desired miniaturization. Moreover, the interval between the light-emitting units of the VCSEL devices 124 can be reduced to prevent the unevenness in light emission.

A light source module 10 that includes the VCSEL array 100 according to the present embodiment is described below.

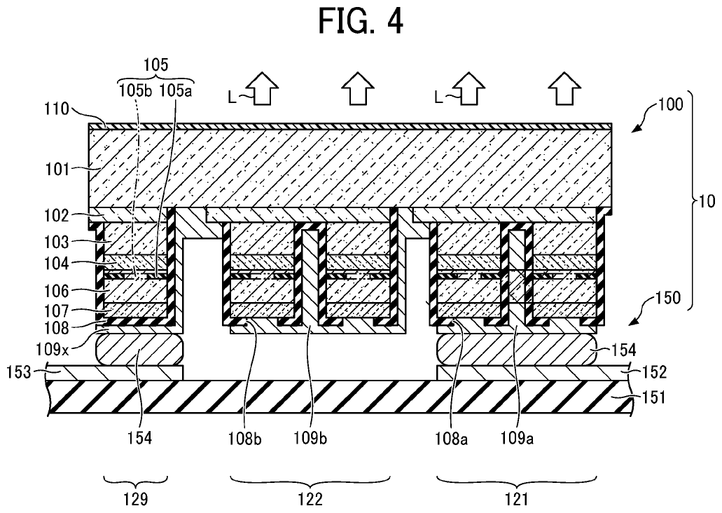

FIG. 4 is a first cross-sectional view of the light source module 10 provided with the VCSEL array 100, according to the first embodiment of the present disclosure.

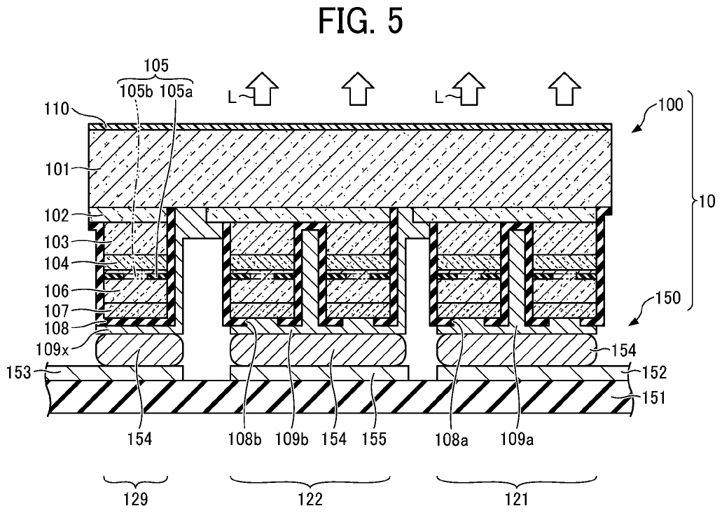

FIG. 5 is a second cross-sectional view of the light source module 10 provided with the VCSEL array 100, according to the first embodiment of the present disclosure.

As illustrated in FIG. 4, the light source module 10 in the first cross-sectional view includes a submount 150 on which the VCSEL array 100 is mounted. The submount 150 according to the present embodiment includes an insulating substrate 151 made of AlN, and electrodes 152 and 153 that are disposed on the insulating substrate 151. The electrode 152 faces the electrode 109a, and the electrode 153 faces the electrode 109x. The light source module 10 has a bonding material 154 between the electrode 152 and the electrode 109a, and has the bonding material 154 between the electrode 153 and the electrode 109x. The submount 150 according to the present embodiment serves as a mounting board.

When the light source module 10 is manufactured, the elements of the VCSEL array 100 are aligned, and the junctions are brought down. Then, these elements of the VCSEL array 100 are bonded together. The bonding material 154 is formed using, for example, a conductive paste and a solder material. The bonding surface may be formed by metal bonding using heat or ultrasonic waves without using a bonding material.

In such a first cross-sectional view of the light source module 10, an electric potential difference is applied from the electrodes 152 and 153 between the electrode 109a and the electrode 109x of the VCSEL array 100.

In the second cross-sectional view of the light source module 10 according to the first embodiment of the present disclosure, as illustrated in FIG. 5, the submount 150 further includes an electrode 155 in addition to the configuration in the first cross-sectional view of the light source module 10. The electrode 155 faces the electrode 109b. The light source module 10 also has the bonding material 154 between the electrode 155 and the electrode 109b. The other configurations in the second cross-sectional view of the light source module 10 are equivalent to those in the first cross-sectional view of the light source module 10.

Also in such a second cross-sectional view of the light source module 10 according to the first embodiment of the present disclosure, an electric potential difference is applied from the electrodes 152 and 153 between the electrode 109a and the electrode 109x of the VCSEL array 100. Although the electrode 155 is not included in the current path, the heat that is generated in the VCSEL devices 124 included in the second sub-array 122 is efficiently released to the submount 150 through the electrode 155 and the bonding material 154 that is placed on the electrode 155.

Both in the first and second cross-sectional views of the light source module 10 according to the first embodiment of the present disclosure, the short circuit between the bonding materials 154 has to be prevented when the light source module 10 is being manufactured. In the present embodiment, one of the electrodes 109a and 109b corresponds to two of the multiple VCSEL devices 124. Accordingly, the distance between two of the multiple bonding materials 154 can be made relatively long, and a short circuit can be easily prevented.

### Modification of First Embodiment

A modification of the first embodiment of the present disclosure is described below.

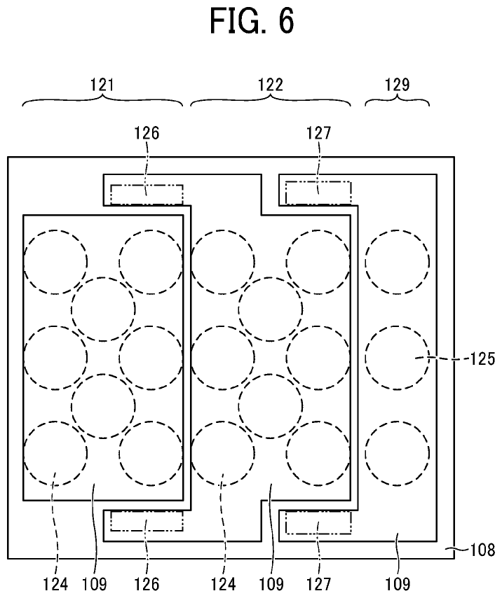

FIG. 6 is a plan view of the VCSEL array 100 according to a modification the first embodiment of the present disclosure.

In the present modification of the first embodiment of the present disclosure, the contact region 126 is not located between the first sub-array 121 and the second sub-array 122, but is located on the side of the first sub-array 121 in a direction perpendicular to the direction in which the first sub-array 121 and the second sub-array 122 are arranged. Accordingly, compared with the configuration or structure according to the first embodiment of the present disclosure, the distance between the VCSEL devices 124 in the first sub-array 121 and the VCSEL devices 124 in the second sub-array 122 is small. As a result, the variations in the spacing among the VCSEL devices 124 in the VCSEL array 100 can be reduced, and the unevenness in light emission can further be prevented. Moreover, further reduction in chip size is enabled.

### Second Embodiment

A second embodiment of the present disclosure is described below. The second embodiment of the present disclosure relates to a VCSEL array.

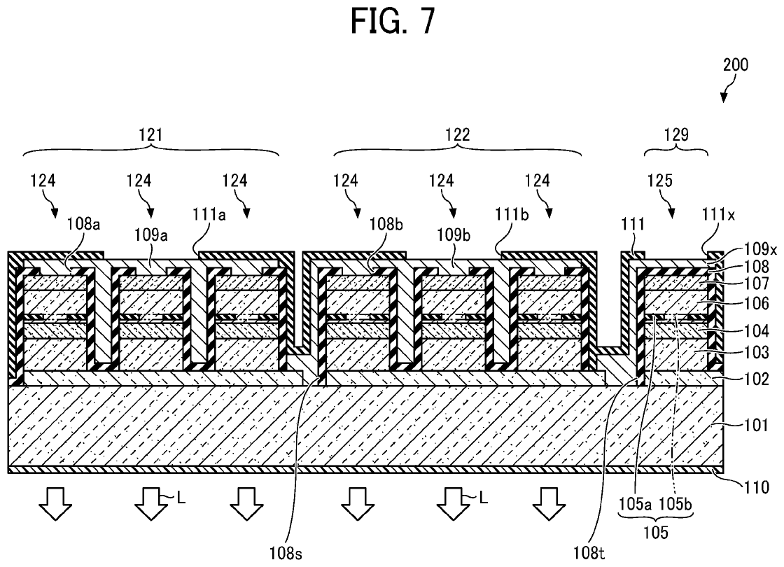

FIG. 7 is a cross-sectional view of a VCSEL array 200 according to the second embodiment of the present disclosure.

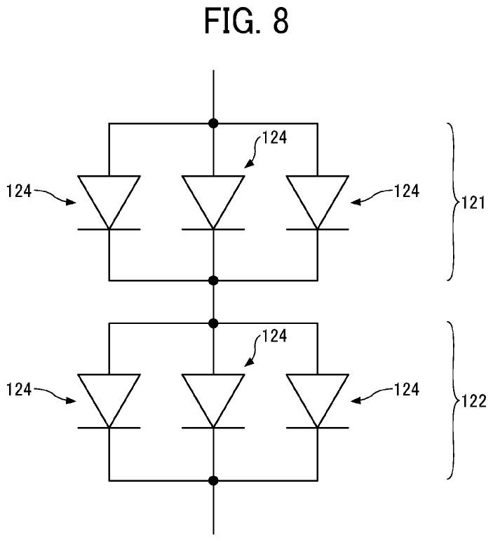

FIG. 8 is a diagram illustrating an equivalent circuit of the VCSEL array 200 according to the second embodiment of the present disclosure.

In the VCSEL array 200 according to the second embodiment of the present disclosure, as illustrated in FIG. 7, each one of the first sub-array 121 and the second sub-array 122 includes three VCSEL devices 124 that emit light L through the substrate 101. As illustrated in FIG. 8, in the first sub-array 121, the three VCSEL devices 124 are electrically connected to each other in parallel. Similarly, in the second sub-array 122, the three VCSEL devices 124 are electrically coupled to each other in parallel.

The VCSEL array 200 according to the present embodiment includes a dielectric layer 111 that convers the electrode 109a, the electrode 109b, and the electrode 109x. The dielectric layer 111 includes an opening 111a that exposes the electrode 109a in the first sub-array 121, an opening 111b that exposes the electrode 109b in the second sub-array 122, and an opening 111x that exposes the electrode 109x in the cathode pad portion 129. The opening 111a is approximately located above the center one of the three VCSEL devices 124 in the first sub-array 121. The opening 111b is approximately located above the center one of the three VCSEL devices 124 in the second sub-array 122. The opening 111x is located at an upper portion of the quasi-VCSEL device 125. A portion of the electrode 109a that is exposed from the opening 111a, a portion of the electrode 109b that is exposed from the opening 111b, and a portion of the electrode 109x that is exposed from the opening 111x together serve as implemented pads. The dielectric layer 111 is, for example, a SiN layer or a SiO₂ layer.

The other aspects of the configuration according to the present embodiment are equivalent to those of the first embodiment as described above.

In the second embodiment, the designer can design the position of the implemented pads independently from the light-emitting points of the VCSEL devices 124. For example, the distance between the light-emitting points of the VCSEL devices 124 between the first sub-array 121 and the second sub-array 122 adjacent to each other is smaller than the distance between the implemented pads adjacent to each other. Accordingly, the unevenness in light emission can further be prevented.

A light source module 20 that includes the VCSEL array 200 according to the present embodiment is described below.

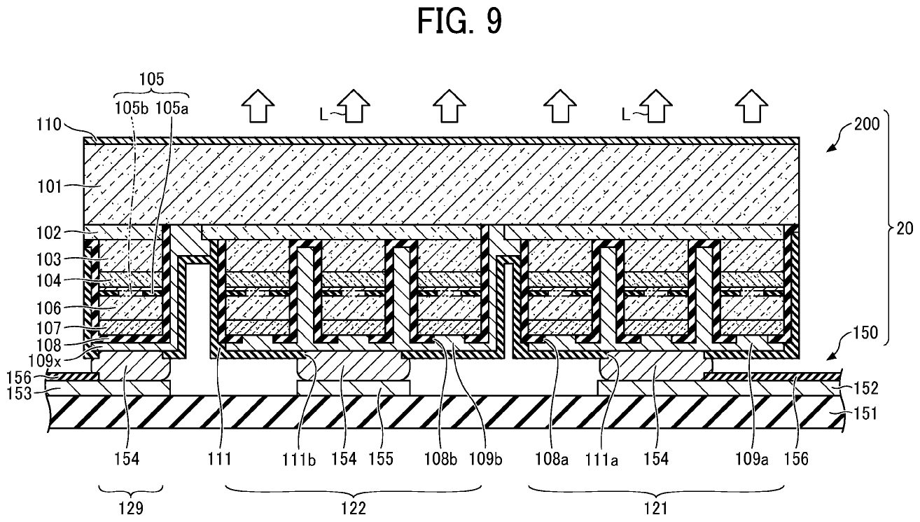

FIG. 9 is a cross-sectional view of the light source module 20 provided with the VCSEL array 200, according to the second embodiment of the present disclosure.

As illustrated in FIG. 9, the light source module 20 according to the present embodiment includes a submount 150 on which the VCSEL array 200 is mounted. The submount 150 according to the present embodiment includes an insulating substrate 151, a dielectric layer 156, and electrodes 152, 153, and 155 disposed on the insulative substrate 151. A plurality of portions of the electrodes 152, 153, and 155 that are exposed from the dielectric layer 156 together serve as the second implemented pad. For example, the implemented pads of the first sub-array 121 has the same planar shape as that of the second implemented pad of the electrode 152. For example, the implemented pads of the second sub-array 122 has the same planar shape as that of the second implemented pad of the electrode 155. For example, the implemented pads of the cathode pad portion 129 has the same planar shape as that of the second implemented pad of the electrode 153. The bonding material 154 is, for example, solder such as Sn—Ag—Cu.

In such a light source module 20 according to the present embodiment, the bonding area where the VCSEL array 200 and the submount 150 are bonded together depends on the dielectric layers 111 and 156, and the light-emitting units of the VCSEL devices 124 are not affected by the bonding area. As described above, for example, the distance between the light-emitting points of the VCSEL devices 124 between the first sub-array 121 and the second sub-array 122 adjacent to each other is smaller than the distance between the implemented pads adjacent to each other. In such cases, a short circuit between the bonding materials 154 can be prevented, and the intervals at which the light-emitting points are arranged can be narrowed. Accordingly, the unevenness in light emission can further be prevented. Moreover, desirable heat-dissipating characteristics can be achieved in a similar manner to the above configuration described with reference to the second cross-sectional view of the light source module 10 in FIG. 5 according to the first embodiment of the present disclosure.

In the related art, the VCSEL devices 124 are formed by lithography and semiconductor processes, and the distance between the bonding materials 154 tends to be longer than the distance between the VCSEL devices 124. According to the present embodiment, the light-emitting units of the VCSEL devices 124 can be disposed without being limited by the intervals at which the implemented pads are arranged.

### Third Embodiment

A third embodiment of the present disclosure is described below. The third embodiment of the present disclosure relates to a VCSEL array.

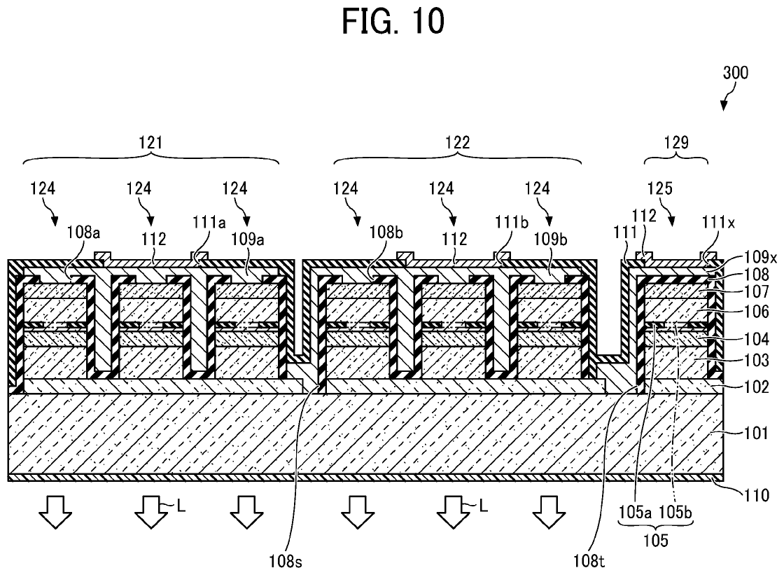

FIG. 10 is a cross-sectional view of a VCSEL array 300 according to the third embodiment of the present disclosure.

As illustrated in FIG. 10, a VCSEL array 300 according to the third embodiment of the present disclosure includes a solder film 112 in an opening 111a, an opening 111b, and an opening 111x. The solder film 112 is formed by, for example, vapor deposition or sputtering. In the third embodiment, the solder film 112 serves as an implemented pad.

The other configurations in the third embodiments of the present disclosure are equivalent to those in the second embodiment of the present disclosure.

Also with the configuration or structure according to the third embodiment of the present disclosure, advantageous effects similar to those of the second embodiment as described above can be achieved. Moreover, the mounting on the submount 150 becomes easy.

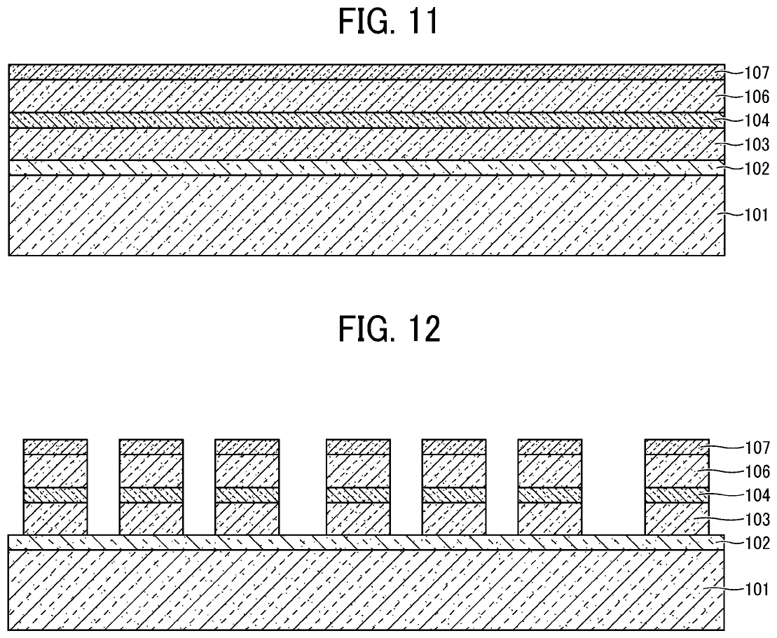

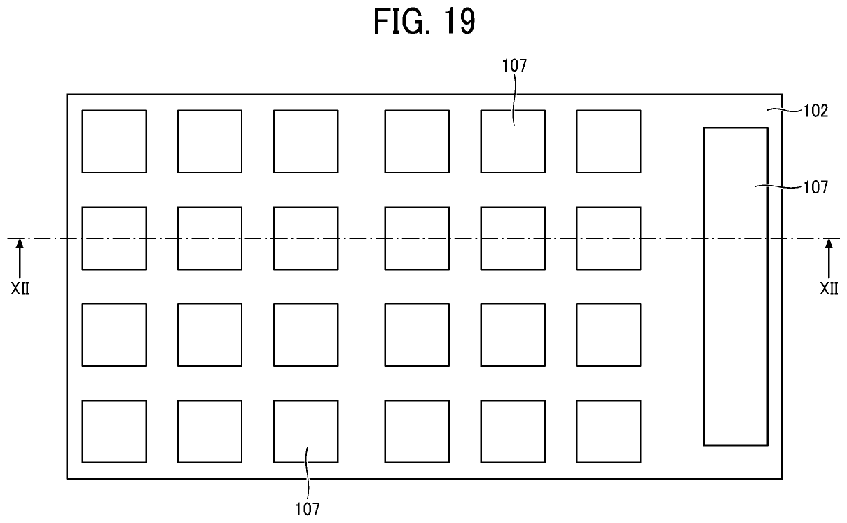

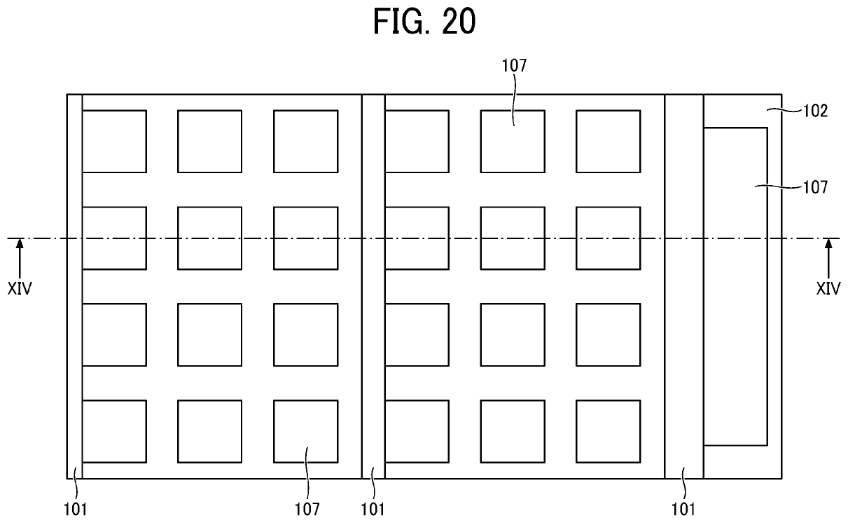

A method of manufacturing the VCSEL array 300 according to the third embodiment of the present disclosure is described below. FIG. 11 to FIG. 18 are cross-sectional views of a method of manufacturing the VCSEL array 300 according to the third embodiment of the present disclosure. FIG. 19 and FIG. 20 are plan views of a method of manufacturing the VCSEL array 300 according to the third embodiment of the present disclosure. The cross-sectional view in FIG. 12 corresponds to a cross section along line XII-XII in FIG. 19, and the cross-sectional view in FIG. 14 corresponds to a cross section along line XIV-XIV in FIG. 20.

FIG. 11 is a first cross-sectional view of a method of manufacturing the VCSEL array 300 according to the third embodiment of the present disclosure.

Firstly, as illustrated in FIG. 11, the first contact layer 102, the first multilayer reflector 103, the resonator 104, the second multilayer reflector 106, and the second contact layer 107 are sequentially grown on a substrate 101. The semiconductor multilayered structure of the first contact layer 102, the first multilayer reflector 103, the resonator 104, the second multilayer reflector 106, and the second contact layer 107 may be made by crystal growth using, for example, metal organic chemical vapor deposition (MOCVD) and molecular beam epitaxy (MBE). In the present embodiment, cases in which metal-organic chemical vapor deposition (MOCVD) is adopted are described. In the MOCVD, for example, trimethylaluminum (TMA), trimethylgallium (TMG), and trimethylindium (TMI) are used as a group III material, and arsine (AsH₃) and phosphine (PH₃) are used as a group V material. Moreover, for example, carbon tetrabromide (CBr₄) is used as a p-type dopant material, and monosilane (SiH₄) is used as a n-type dopant material.

As the substrate 101, for example, a semi-insulating GaAs substrate may be used.

The first contact layer 102 is, for example, an n-type GaAs layer whose thickness is 3 μm. In order to prevent over etching of the first contact layer 102, an etch stop layer such as an AlGaInP layer or a GaInP layer may be formed between the first contact layer 102 and the first multilayer reflector 103.

The first multilayer reflector 103 includes 24.5 pairs of a high refractive index layer and a low refractive index layer. For example, the high refractive index layer is a n-type Al_{0.2}Ga_{0.8}As layer, and the low refractive index layer is a n-type Al_{0.9}Ga_{0.1}As layer. A gradient-composition layer whose thickness is 20 nm is formed between the high refractive index layer and the low refractive index layer in order to reduce electrical resistance. Assuming that λ denotes the oscillation wavelength, the optical thickness of the high refractive index layer and the low refractive index layer is λ/4 including the half of the adjacent gradient-composition layer. When the optical thickness is λ/4, the actual thickness D of the layer is indicated by an equation given below. D=λ/4n In the above equation, n denotes the refractive index of the medium of that layer.

The resonator 104 includes a lower spacer layer, an active layer over the lower spacer layer, and an upper spacer layer over the active layer. λ denotes optical length of the resonator 104. For example, the oscillation wave length λ is 940 nm. The lower spacer layer and the upper spacer layer are, for example, Al_{0.4}Ga_{0.6}As layers. The active layer has a triple-bond quantum well structure. For example, those quantum well layers are composed of, for example, InGaAs, and those barrier layers are composed of, for example, Al_{0.1}GaAs. The active layer is formed in the center of the resonator 104. For example, the oscillation wave length λ is 940 nm.

The second multilayer reflector 106 includes thirty-eight pairs of a high refractive index layer and a low refractive index layer. For example, the high refractive index layer is a p-type Al_{0.2}Ga_{0.8}As layer, and the low refractive index layer is a p-type Al_{0.9}Ga_{0.1}As layer. A gradient-composition layer whose thickness is 20 nm is formed between the high refractive index layer and the low refractive index layer in order to reduce electrical resistance.

Assuming that λ denotes the oscillation wavelength, the optical thickness of the high refractive index layer and the low refractive index layer is λ/4 including the half of the adjacent gradient-composition layer.

The second multilayer reflector 106 includes, for example, a selective oxidized layer 105 made of p-AlAs. The selective oxidized layer 105 is positioned at an optical distance of λ/4 from the interface between the second multilayer reflector 106 and the resonator 104. The selective oxidized layer 105 may include, for example, a gradient-composition layer and an intermediate layer in the up-and-down directions.

The second contact layer 107 is, for example, a p-type GaAs layer.

FIG. 12 is an eighth cross-sectional view of a method of manufacturing the VCSEL array 300 according to the third embodiment of the present disclosure.

FIG. 19 is a first plan view of a method of manufacturing the VCSEL array 300 according to the third embodiment of the present disclosure.

After the semiconductor multilayered structure is formed, photomechanical processes or photo engraving are used, and for example, a square resist pattern having a side length of 30 μm and a rectangular resist pattern having a side length of 80 μm×200 μm are formed on the second contact layer 107. The square resist pattern is formed in a region where the VCSEL devices 124 is to be formed, and the rectangular resist pattern is formed in a region where the quasi-VCSEL device 125 is to be formed. Subsequently, the above resist patterns are used as mask, and as illustrated in FIG. 12 and FIG. 19, the semiconductor laminated structure is etched by electron cyclotron resonance (ECR) etching using Cl₂ gas such that the first contact layer 102 will be exposed as a bottom. As a result, a mesa structure is formed. The mesa structure is formed such that at least the selective oxidized layer 105 will be exposed. After etching, the resist pattern is removed.

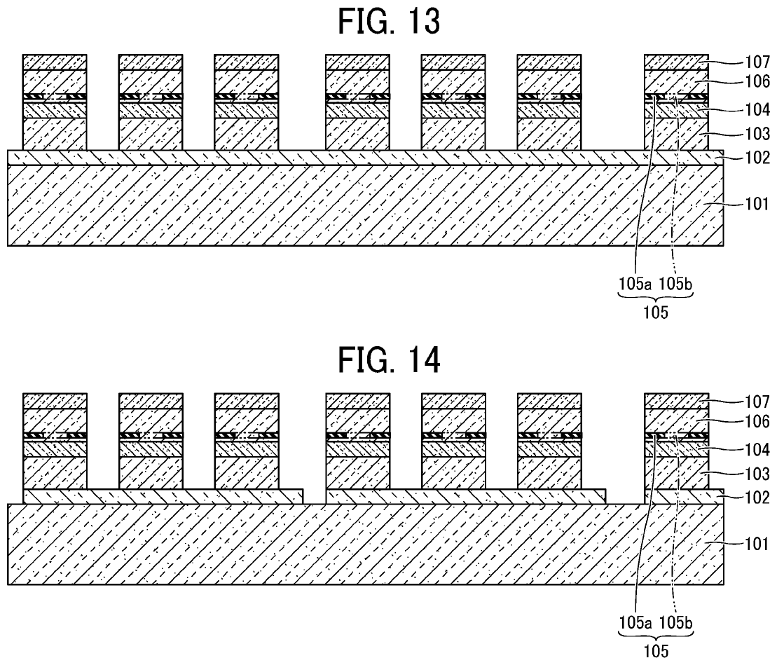

FIG. 13 is a third cross-sectional view of a method of manufacturing the VCSEL array 300 according to the third embodiment of the present disclosure.

Subsequently, as an object to be oxidized, the semiconductor multilayered structure having the mesa structure formed therein is subjected to heat treatment or oxidation in vapor. As a result, Al in the selective oxidized layer 105 is selectively oxidized from the outer peripheral portion of the mesa structure. As illustrated in FIG. 13, the non-oxidized area 101a that is surrounded by the non-oxidized area 105b of Al remains in the center of the mesa structure. As a result, an oxidation constriction structure is formed that limits the path of the driving current of the light-emitting units to the center of the mesa structure. The non-oxidized area 105b is a current-carrying area or a current injecting area. As described above, in the present modification of the above embodiments of the present disclosure, for example, an approximately square-shaped current-carrying area whose side length is 10 μm is formed.

FIG. 14 is a fourth cross-sectional view of a method of manufacturing the VCSEL array 300 according to the third embodiment of the present disclosure.

FIG. 20 is a second plan view of a method of manufacturing the VCSEL array 300 according to the third embodiment of the present disclosure.

Subsequently, a resist pattern is formed on the first contact layer 102 and the second contact layer 107 using photomechanical processes or photo engraving. The resist pattern has openings between a region where the first sub-array 121 is to be formed and a region where the second sub-array 122 is to be formed, and between a region where the second sub-array 122 is to be formed and a region where the cathode pad portion 129 is to be formed. The width of the opening is, for example, 20 micrometers (μm). Subsequently, the above resist patterns are used as mask, and as illustrated in FIG. 14 and FIG. 20, the first contact layer 102 is etched by electron cyclotron resonance (ECR) etching using Cl₂ gas, such that the substrate 101 is exposed as a bottom. As a result, a groove having a width of 20 μm is formed in the first contact layer 102. The groove electrically insulates the first contact layer 102 in the first sub-array 121, the first contact layer 102 in the second sub-array 122, and the first contact layer 102 in the cathode pad portion 129. The groove may be formed by a wet etching method using a solvent.

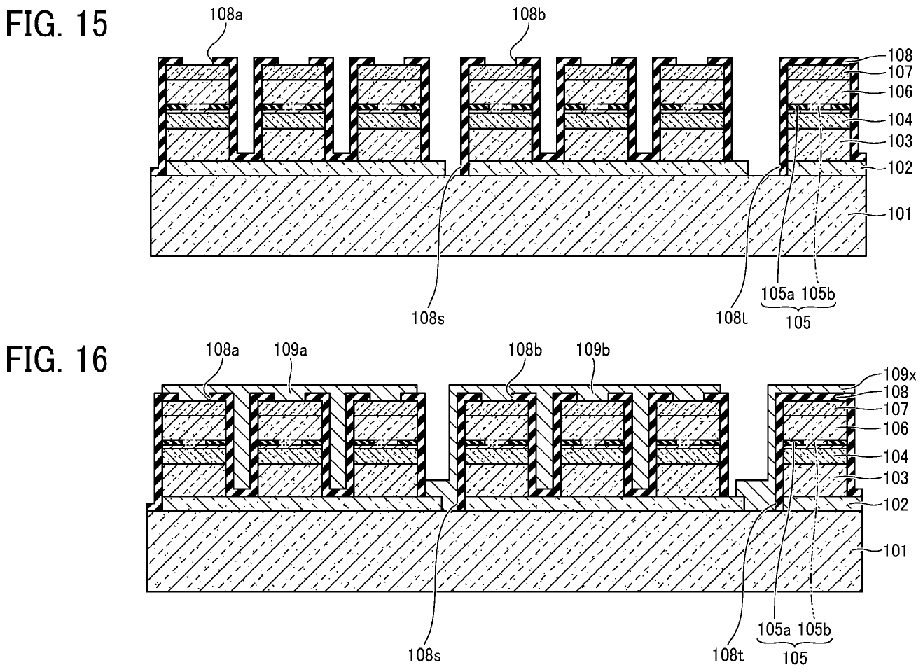

FIG. 15 is a fifth cross-sectional view of a method of manufacturing the VCSEL array 300 according to the third embodiment of the present disclosure.

Subsequently, as illustrated in FIG. 15, an optically transparent insulating layer 108 that covers the mesa structure is formed using, for example, a plasma-enhanced chemical vapor deposition (CVD). insulating layer

The insulating layer 108 according to the present embodiment is, for example, a SiN layer. Subsequently, photomechanical processes or photo engraving are performed, and an openings 108a and 108b and openings 108s and 108t are formed in the insulating layer 108 by etching using, for example, buffered hydrofluoric acid (BHF).

FIG. 16 is a sixth cross-sectional view of a method of manufacturing the VCSEL array 300 according to the third embodiment of the present disclosure.

Subsequently, a resist pattern is formed by photolithography, a metallic film is formed, and lift-off is performed, thereby forming electrodes 109a, 109b, and 109x as illustrated in FIG. 16. The metal film is, for example, a stacked body including a Ti film, a Pt film on the Ti film, and an Au film on the Pt film. A base layer for ohmic connection with the first contact layer 102 and a base layer for ohmic connection with the second contact layer 107 may be different from each other. In such cases, the deposition and lift-off may be performed twice or three times.

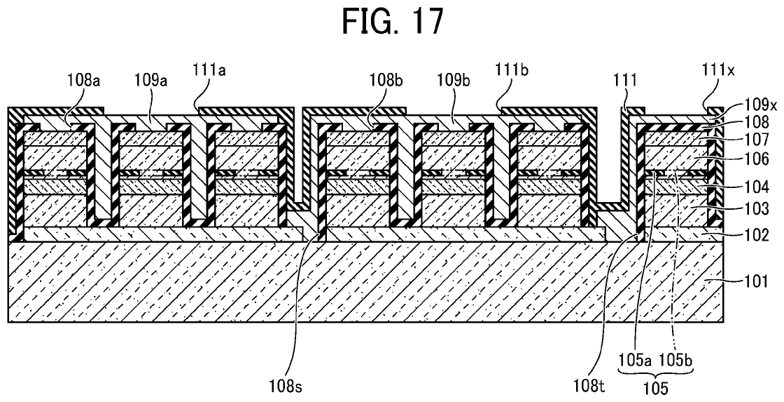

FIG. 17 is a seventh cross-sectional view of a method of manufacturing the VCSEL array 300 according to the third embodiment of the present disclosure.

Subsequently, as illustrated in FIG. 17, an optically transparent dielectric layer 111 that covers the electrodes 109a, 109b, and 109x is formed using, for example, a plasma-enhanced chemical vapor deposition (plasma CVD) method. The dielectric layer 111 is, for example, a SiN layer.

Subsequently, photomechanical processes or photo engraving are performed, and an opening 111a, an opening 111b, and an opening 111x are formed in the dielectric layer 111 by etching using, for example, buffered hydrofluoric acid (BHF).

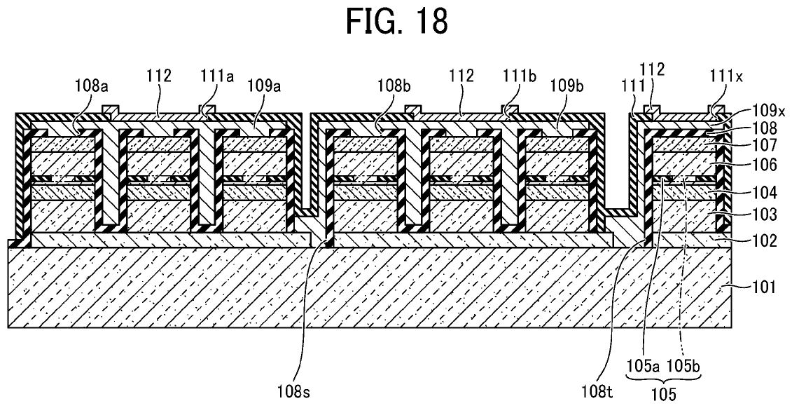

FIG. 18 is an eighth cross-sectional view of a method of manufacturing the VCSEL array 300 according to the third embodiment of the present disclosure.

Subsequently, as illustrated in FIG. 18, a solder film 112 is formed. In the formation of the solder film 112, firstly, a seed layer is formed by sputtering or the like. The seed layer includes, for example, a Ti film and a Cu film that is placed on the Ti film. Subsequently, a resist pattern is formed on the seed layer using photomechanical processes or photo engraving. The resist pattern has an opening only in an area used for the implementation with the submount 150.

The distance between an adjacent pair of openings is, for example, 200 μm. It is desired that the above distance be set in view of the subsequent implementation processes to prevent the short circuit between a pair of adjacent implemented pads. Subsequently, a solder film 112 is selectively formed in the opening by electrolytic plating. The material of the solder film 112 is, for example, SnAg, SnAgCu, and SuAu. An adhesion layer such as a Ni layer or a Cr layer may be formed between the seed layer and the solder film 112. After the solder film 112 is formed, the resist pattern is removed, and the entire surface is etched back by, for example, reverse sputtering to remove the exposed seed layer.

Subsequently, the rear side of the substrate 101 from which light is emitted is polished to a mirror-smooth state by, for example, chemical mechanical polishing (CMP). Subsequently, an antireflection film 110 is formed on the surface of the substrate 101 from which light is emitted. The antireflection film 110 is formed by, for example, plasma-enhanced CVD. The antireflection film 110 is, for example, a SiN film whose optical thickness is indicated by λ/4.

In this manner, the VCSEL array 300 according to the third embodiment of the present disclosure is manufactured.

### Fourth Embodiment

A fourth embodiment of the present disclosure is described below. The fourth embodiment of the present disclosure relates to a VCSEL array.

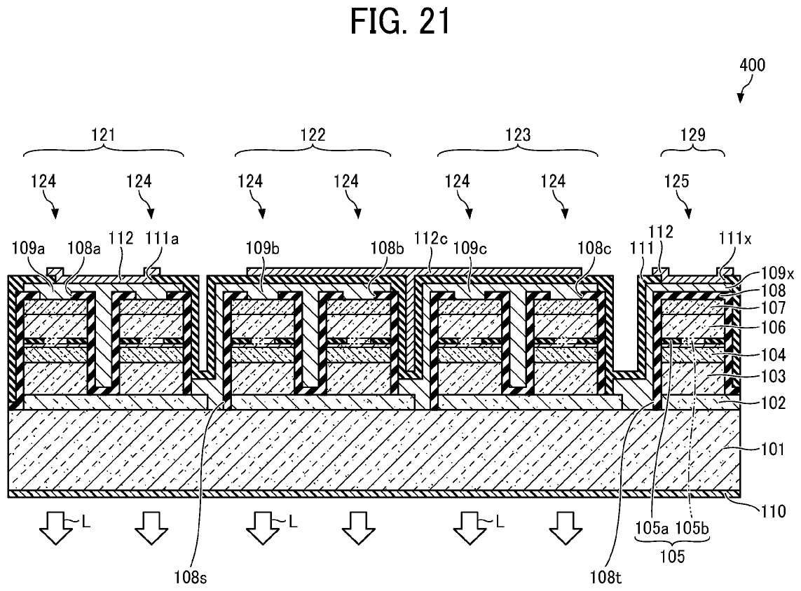

FIG. 21 is a cross-sectional view of a VCSEL array 400 according to the fourth embodiment of the present disclosure.

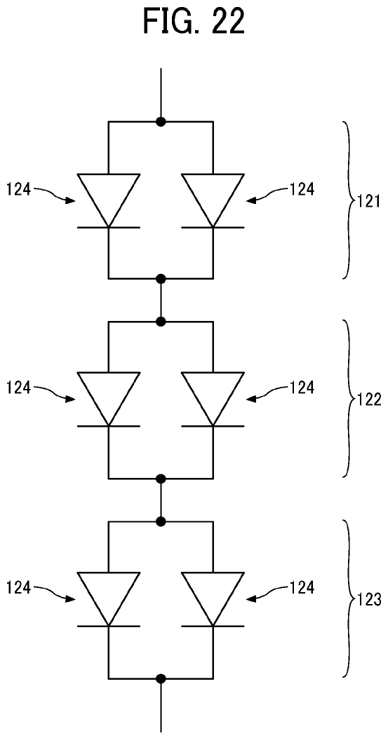

FIG. 22 is a diagram illustrating an equivalent circuit of the VCSEL array 400, according to the fourth embodiment of the present disclosure.

As illustrated in FIG. 21, the VCSEL array 400 according to the fourth embodiment includes the substrate 101, and the first sub-array 121, the second sub-array 122, the third sub-array 123, and the cathode pad portion 129 that are disposed on the substrate 101. As illustrated in FIG. 22, the first sub-array 121, the second sub-array 122, and the third sub-array 123 are coupled to each other in series. Each one of the first sub-array 121, the second sub-array 122, and the third sub-array 123 includes two VCSEL devices 124 that emit light L through the substrate 101. In the first sub-array 121, the two VCSEL devices 124 are electrically connected to each other in parallel. Similarly, in the second sub-array 122, the two VCSEL devices 124 are electrically connected to each other in parallel. Similarly, in the third sub-array 123, the two VCSEL devices 124 are electrically coupled to each other in parallel. As illustrated in FIG. 21, the third sub-array 123 is placed between the second sub-array 122 and the cathode pad portion 129.

In addition to the openings 108a and 108b, the insulating layer 108 has an opening 108c that exposes the second contact layers 107 of the two VCSEL devices 124 included in the third sub-array 123. In addition to the openings 108s and 108t, the insulating layer 108 has an opening 108u that exposes the first contact layers 102 included in the third sub-array 123.

In addition to the electrodes 109a, 109b, and 109x, the VCSEL array 100 includes an electrode 109c that is disposed on the insulating layer 108. The electrode 109c contacts the second contact layers 107 of the two VCSEL devices 124 included in the third sub-array 123 through the opening 108c.

The dielectric layer 111 has an opening 111a and a 111x, but does not have an opening 111b. Accordingly, the dielectric layer 111 covers the entirety of the electrodes 109b and 109c. The VCSEL array 400 has a solder film 112 in the opening 111a and in the opening 111x. The VCSEL array 400 further includes a solder film 112c that extends over the second sub-array 122 and the third sub-array 123. The solder film 112c may enter the space of the dielectric layer 111 between the second sub-array 122 and the third sub-array 123. In the fourth embodiment, the solder films 112 and 112c serve as the implemented pad. The solder film 112 according to the present embodiment serves as a conductive pad, and the solder film 112c according to the present embodiment serves as a non-conductive pad. When a short circuit occurs between the conductive pad and the non-conductive pad, the parasitic capacitance of the implemented pad in which the short circuit occurs increases, and the high-speed responsiveness tends to be impaired. In order to handle such a situation, it is desired that the interval between adjacent implemented pads, which is the interval between the solder film 112 and the solder film 112c, be wider than the interval between the first sub-array 121 and the second sub-array 122 that are adjacent to each other. By so doing, the short circuit the conductive pad and the non-conductive pad can be prevented from occurring.

The other configurations in the fourth embodiments of the present disclosure are equivalent to those in the third embodiment of the present disclosure.

A light source module 40 that includes the VCSEL array 400 according to the present embodiment is described below.

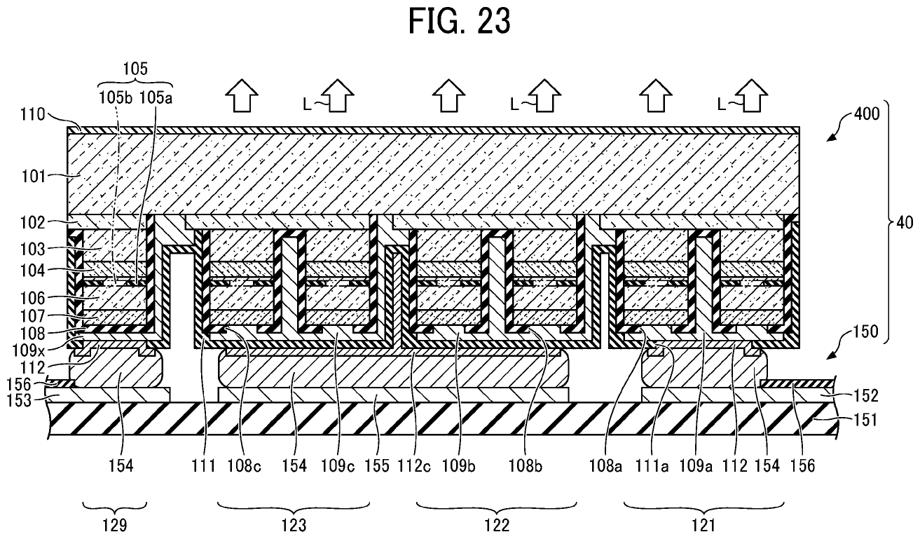

FIG. 23 is a cross-sectional view of the light source module 40 provided with the VCSEL array 400, according to the fourth embodiment of the present disclosure.

As illustrated in FIG. 23, the light source module 40 according to the present embodiment includes a submount 150 on which the VCSEL array 400 is mounted. The submount 150 according to the present embodiment includes an insulating substrate 151, a dielectric layer 156, and electrodes 152, 153, and 155 disposed on the insulative substrate 151. A plurality of portions of the electrodes 152, 153, and 155 that are exposed from the dielectric layer 156 together serve as the second implemented pad. For example, the implemented pads of the first sub-array 121 has the same planar shape as that of the second implemented pad of the electrode 152. For example, the implemented pads of the second sub-array 122 and the third sub-array 123, which serve as a solder film 112c, has the same planar shape as that of the second implemented pads of the electrode 155. For example, the implemented pads of the cathode pad portion 129 has the same planar shape as that of the second implemented pad of the electrode 153.

Also with the configuration or structure according to the fourth embodiment of the present disclosure, advantageous effects similar to those of the third embodiment as described above can be achieved. The multiple implemented pads can be integrated into one unit without electrically shorting the second sub-array 122 and the third sub-array 123. Due to such a configuration, the number of sub-arrays is equal to the number of implemented pads. Although the electrode 155 is not included in the current path, the heat that is generated in the VCSEL devices 124 included in the second sub-array 122 and the heat that is generated in the VCSEL devices 124 included in the third sub-array 123 are efficiently released to the submount 150 through the electrode 155 and the bonding material 154 that is placed on the electrode 155. In the fourth embodiment of the present disclosure, the space of the implemented pad is not always necessary between the second sub-array 122 and the third sub-array 123. Accordingly, the bonding area can be widened, and further desirable heat dissipation characteristics can be obtained.

Although the VCSEL array 400 according to the fourth embodiment has three sub-arrays 121, 122, 123, the number of implemented pads can be three even if the number of sub-arrays 121, 122, 123 is four or more. For example, even if the number of sub-arrays is four or five, the VCSEL array may have the implemented pad of the first sub-array 121, the implemented pad of the cathode pad portion 129, and the implemented pad for heat dissipation not included in the current path. In such a case, the number of implemented pads is less than the number of sub-arrays. For example, when the number of sub-arrays 121, 122, 123 is five, the implemented pads that are not included in a current path and are not electrically connected may be divided into two areas, and the number of implemented pads may be four.

Instead of forming the groove by etching, the electrical insulation between a pair of the multiple first contact layers 102 adjacent to each other may be performed by ion implantation of, for example, hydrogen.

In the above embodiments of the present disclosure, the substrate 101 is a semi-insulating GaAs substrate in order to electrically insulate the semiconductor multilayered structure from the substrate 101. However, no limitation is indicated thereby, and the substrate 101 is not limited to the semi-insulating GaAs substrate. For example, if there is a non-doped GaAs layer between the substrate 101 and the first contact layer 102, the substrate 101 may be an n-type GaAs substrate.

### Fifth Embodiment

A fifth embodiment of the present disclosure is described below. The fifth embodiment of the present disclosure relates to a distance-measuring apparatus 500. The distance-measuring apparatus 500 according to the present embodiment serves as an optical device.

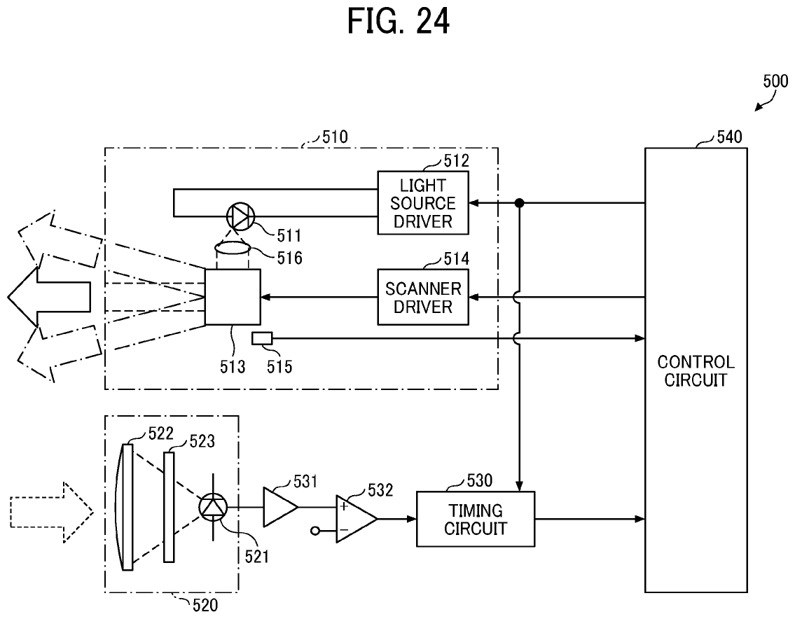

FIG. 24 is a diagram illustrating a configuration of the distance-measuring apparatus 500 according to the fifth embodiment of the present disclosure.

The distance-measuring apparatus 500 according to the fifth embodiment includes a light emitter 510, a light-receiving unit 520, a timing circuit 530, and a control circuit 540.

For example, the light emitter 510 includes a light source 511, a light source driver 512, an optical scanner 513, a scanner driver 514, a scanning-angle monitor 515, and a projection lens 516. The light source 511 includes a light source module having the VCSEL array according to the first to fourth embodiments of the present disclosure. The light source driver 512 drives the light source 511 based on the driving signal output from the control circuit 540. The optical scanner 513 includes, for example, a micro-electromechanical systems (MEMS) mirror or a polygon mirror. The scanner driver 514 drives the optical scanner 513 based on the driving signal output from the control circuit 540. The light source module of the light source 511 has a plurality of sub-arrays. Each one of the multiple sub-arrays includes at least one VCSEL device, and the VCSEL devices of each one of the multiple sub-arrays are electrically connected to each other in parallel. The multiple sub-arrays are one-dimensionally arranged in the scanning direction or sub-scanning direction of the optical scanner 513. For example, the light source driver 512 drives the light source module of the light source 511 with pulse current on the order of nanoseconds (ns). The laser beams that are emitted from the VCSEL device are converted into the light of desired beam profile, where appropriate, by the projection lens 516 or the like, and then, the irradiation direction of the light is determined by the optical scanner 513, and the light is emitted to the outside of the distance-measuring apparatus 500. The scanning angle of the optical scanner 513 is measured by the scanning-angle monitor 515, and the result of such measurement is output to the control circuit 540. Each one of the optical scanner 513 and the projection lens 516 according to the present embodiment serves as an optical element.

The laser beams that are emitted to the outside of the distance-measuring apparatus 500 are reflected by an object, and return to the distance-measuring apparatus 500 and reaches the light-receiving unit 520.

For example, the light-receiving unit 520 includes a light receiver 521, a light-receptive lens 522, and a band-pass filter 523. The light receiver 521 includes an avalanche photodiode (APD) device made of silicon (Si). The light-receptive lens 522 makes the light that has reached the light-receiving unit 520 converge to the light receiver 521. The band-pass filter 523 includes a dielectric multilayer, and is designed to let only the light of oscillation wavelength of the light source 511 pass. Due to the band-pass filter 523, the signal-to-noise (S/N) ratio of signals can be improved.

The light that has reached the light receiver 521 is converted into an electrical signal by the light receiver 521, and is input to the timing circuit 530 through an amplifier and a comparator 532. The electrical signal may be processed by the amplifier 531 or the comparator 532 on an as-needed basis.

A driving signal for the light source 511 that is output from the control circuit 540 and a signal that is sent from the light receiver 521 are input to the timing circuit 530. The timing circuit 530 calculates the delay time between these two kinds of signals, and outputs the result of calculation to the control circuit 540.

The control circuit 540 converts the delay time from the timing circuit 530 into an optical wavelength.

According to the distance-measuring apparatus 500 as described above, the distance to the object is measured, and laser beams are sequentially emitted to the sub-light-emitting areas of the light source module and the regions of space that are split by the optical scanner 513. Due to this configuration, two-dimensional distance information can be obtained. For example, this distance-measuring apparatus 500 may be used for light detection and ranging (LiDAR).

The light source module according to the embodiments or their modifications of the present disclosure may be used for a excitation light source or excitation light source of solid-state laser, instead of the light source of a distance-measuring apparatus. Moreover, the surface-emitting laser module according to the embodiments or their modifications of the present disclosure may be used as a light-source device such as a projector, in combination with an optical element that converts the wavelength of the light exiting from a surface-emitting laser module such as a fluorescent material. Further, the surface-emitting laser module may be used as a light source device for sensing in combination with an optical element that diverges or converges the light emitted from the surface-emitting laser module such as a lens, a mirror, and a diffraction grating.

Note that numerous additional modifications and variations are possible in light of the above teachings. It is therefore to be understood that within the scope of the appended claims, the disclosure of the present disclosure may be practiced otherwise than as specifically described herein. For example, elements and/or features of different illustrative embodiments may be combined with each other and/or substituted for each other within the scope of this disclosure and appended claims.

This patent application is based on and claims priority to Japanese Patent Application No. 2021-040536, filed on Mar. 12, 2021, in the Japan Patent Office, the entire disclosure of which is hereby incorporated by reference herein.

### REFERENCE SIGNS LIST

10, 20, 40 Light source module
100, 200, 300, 400 Vertical-cavity surface-emitting laser (VCSEL) array
101 Substrate
102, 107 Contact layer
105 Selective oxidized layer
109a, 109b, 109c, 109x Electrode
121, 122, 123 Sub-array
124 VCSEL device
125 Quasi-VCSEL device
129 Cathode pad portion
150 Submount
500 Distance-measuring apparatus

1. A surface-emitting laser array comprising:
a substrate;
a plurality of sub-arrays disposed on the substrate, the plurality of sub-arrays including a plurality of surface-emitting laser devices electrically connected to each other in parallel to emit light through the substrate, each of the plurality of surface-emitting laser devices having a light-emitting point and including
a first semi-conducting layer of first conductivity,
a second semi-conducting layer of second conductivity, and
a resonator disposed between the first semi-conducting layer and the second semi-conducting layer,
wherein the plurality of sub-arrays that are adjacent to each other include an electrode to electrically connect the first semi-conducting layer in the plurality of surface-emitting laser devices included in one of the plurality of sub-arrays and the second semi-conducting layer in the plurality of surface-emitting laser devices included in another one of the plurality of sub-arrays, and
wherein the plurality of sub-arrays are electrically connected in series.

2. The surface-emitting laser array according to claim 1, further comprising:
a plurality of implemented pads to be mounted on a mounting board,
wherein at least one of the plurality of implemented pads is disposed on at least one of the plurality of sub-arrays.

3. The surface-emitting laser array according to claim 2,
wherein the plurality of implemented pads include a first implemented pad and a second implemented pad adjacent to the first implemented pad, and
wherein a distance between a first sub-array on which the first implemented pad is disposed and a second sub-array adjacent to the first sub-array is narrower than a distance between the first implemented pad and the second implemented pad.

4. The surface-emitting laser array according to claim 3,
wherein, between the first sub-array and the second sub-array, a distance between the light-emitting point of one of the plurality of surface-emitting laser devices and the light-emitting point of another neighboring one of the plurality of surface-emitting laser devices is smaller than a distance between the second implemented pad and the first implemented pad.

5. The surface-emitting laser array according to claim 3,
wherein the plurality of implemented pads are not disposed on the second sub-array.

6. The surface-emitting laser array according to claim 3,
wherein the second implemented pad is disposed on the second sub-array,
wherein the second implemented pad is smaller than the second sub-array, and
wherein the second implemented pad is another one of the plurality of implemented pads.

7. The surface-emitting laser array according to claim 2,
wherein a number of the plurality of implemented pads is equal to or less than a number of the plurality of sub-arrays.

8. The surface-emitting laser array according to claim 2,
wherein a number of the plurality of implemented pads is three or more.

9. The surface-emitting laser array according to claim 2,
wherein each one of the plurality of implemented pads comprises:
a conductive pad coupled to the electrode; and
a non-conductive pad insulated from the electrode.

10. The surface-emitting laser array according to claim 3,
wherein the first implemented pad is a conductive pad coupled to the electrode, and
wherein another one of the plurality of implemented pads is the conductive pad or a non-conductive pad insulated from the electrode.

11. The surface-emitting laser array according to claim 1,
wherein a distance between two of the plurality of light-emitting points of the plurality of surface-emitting laser devices in an adjacent pair of the plurality of sub-arrays is equivalent to a distance between two of the plurality of light-emitting points of the plurality of surface-emitting laser devices in an adjacent pair of the plurality of sub-arrays.

12. A light source module comprising:
the surface-emitting laser array according to claim 2; and
the mounting board on which the surface-emitting laser array is mounted.

13. The light source module according to claim 12,
wherein the mounting board comprises a second implemented pad electrically connected to the plurality of implemented pads provided for the surface-emitting laser array, and
wherein the second implemented pad has a planar shape equivalent to a planar shape of the plurality of implemented pads.

14. A distance-measuring apparatus comprising:
the light source module according to claim 12, and
an optical element on which light emitted from the light source module is incident.
